(19) United States
(12) Patent Application Publication
(10) Pub. No.: US 2005/0183665 A1
(43) Pub. Date: Aug. 25, 2005

(54) Apparatus for manufacturing flat-panel display

(75) Inventors: Young Jong Lee, Sungnam-shi (KR); Jun Young Choi, Seoul (KR); Saeng Hyun Jo, Daejeon (KR); Sung Il Ahn, ChungCheongNam-do (KR)

Correspondence Address: DALY, CROWLEY, MOFFORD & DURKEE, LLP, SUITE 301A, 354A TURNPIKE STREET, CANTON, MA, 02021-2714, US

(73) Assignee: Advanced Display Process Engineering Co., Ltd.

(21) Appl. No.: 11/064,150

(22) Filed: Feb. 23, 2005

(30) Foreign Application Priority Data
Feb. 24, 2004 (KR) 10-2004-0012266
Jun. 17, 2004 (KR) 10-2004-0045093
Feb. 27, 2004 (KR) 10-2004-0013407

(51) Int. Cl. C23C 16/00

(52) U.S. Cl. 118/715

(57) ABSTRACT

A flat-panel display (FPD) manufacturing apparatus is disclosed which not only includes a load lock chamber, a feeding chamber, and a processing chamber, at least one of which has a vertically-stacked chamber structure to achieve an enhancement in substrate processing efficiency, but also includes a temporary substrate storing space for temporarily storing substrates in the feeding chamber to reduce the time taken to feed substrates. Another FPD manufacturing apparatus is disclosed which includes a load lock chamber, a feeding chamber connected to the load lock chamber, a temporary substrate storing space arranged at a predetermined portion of the feeding chamber, and at least one processing chamber connected to the feeding chamber.

### BACKGROUND OF THE INVENTION

1. Field of the Invention

The present invention relates to an apparatus for manufacturing a flat-panel display (FPD). More particularly, the present invention relates to an FPD manufacturing apparatus which not only includes a load lock chamber, a feeding chamber, and a processing chamber, at least one of which has a vertically-stacked chamber structure to achieve an enhancement in substrate processing efficiency, but also includes a temporary substrate storing space for temporarily storing substrates in the feeding chamber to reduce the time taken to feed substrates.

2. Description of the Related Art

Referring to FIG. 1, a general flat-panel display (FPD) manufacturing apparatus is illustrated. The FPD manufacturing apparatus includes a load lock chamber 10, a feeding chamber 20, and a processing chamber 30, which are connected in series to process a substrate for an FPD.

The load lock chamber 10 is connected to an external station, in order to receive a substrate to be processed in the FPD manufacturing apparatus for loading of the substrate or to discharge a substrate completely processed in the FPD manufacturing apparatus for unloading of the substrate. The load lock chamber 10 is repeatedly switched between a vacuum state and an atmospheric state, so that the load lock chamber 10 is selectively communicated with the external station.

A loading die 11 is arranged in the load lock chamber 10, in order to load one or more substrates on the loading die 11. An exhausting device (not shown) and a gas supplier (not shown) are also installed in the load lock chamber 10, in order to change the atmosphere of the load lock chamber 10 between a vacuum state and an atmospheric state.

The feeding chamber 20 is connected between the load lock chamber 10 and the processing chamber 30. As shown in FIG. 1, the feeding chamber 20 is provided with a feeding robot 21 arranged in the interior of the feeding chamber 20, so that the feeding chamber 20 serves as an intermediate passage for feeding a substrate between the load lock chamber 10 and the processing chamber 30 for loading/unloading of the substrate. The feeding chamber 20 is maintained in a vacuum atmosphere so that the processing chamber 30 is maintained in a vacuum atmosphere even when a substrate is unloaded from the processing chamber 30 or is loaded into the processing chamber 30.

Also, the processing chamber 30 is equipped with a processing device 31 to perform a desired process for the substrate loaded in the processing chamber 30. For example, an etching process is carried out in a vacuum atmosphere established in the processing chamber 30.

In order to load a substrate, to be processed, from an external station into the processing chamber, the substrate must always pass through the load lock chamber and feeding chamber in the above-mentioned conventional FPD manufacturing apparatus. For this reason, much time is taken to load the substrate, thereby causing a degradation in substrate processing efficiency. Such a problem also occurs when a substrate is unloaded from the processing chamber to the external station.

Recently, this problem has become more severe due to an increase in the time taken to transport substrates inevitably caused by the recent trend of FPDs to have an increased size. Furthermore, in the case of an FPD manufacturing apparatus adapted to manufacture large-size FPDs, it is necessary to increase the substrate processing efficiency of the FPD manufacturing apparatuses because an increase in the area of the FPD manufacturing apparatus in a clean room occurs inevitably. For this reason, the above-mentioned problem becomes more serious.

### SUMMARY OF THE INVENTION

Therefore, it is an object of the invention to provide an FPD manufacturing apparatus in which a temporary substrate storing space is provided in a feeding chamber to reduce substrate loading and unloading times.

Another object of the invention is to provide an FPD manufacturing apparatus in which a selected one of the chambers included in the FPD manufacturing apparatus has a stacked chamber structure, thereby being capable of achieving a reduction in installation area while achieving an enhancement in substrate processing efficiency.

Another object of the invention is to provide an FPD manufacturing apparatus in which a processing chamber of the FPD manufacturing apparatus has a stacked or multi-layer chamber structure, whereas a load lock chamber and a feeding chamber of the FPD manufacturing apparatus have a single-layer chamber structure.

Another object of the invention is to provide an FPD manufacturing apparatus which includes a load lock chamber divided into upper and lower chamber sections capable of feeding substrates independently of each other.

In accordance with one aspect, the present invention provides a flat-panel display manufacturing apparatus comprising a load lock chamber and a feeding chamber connected to the load lock chamber, the apparatus further comprising: a temporary substrate storing space arranged at a predetermined portion of the feeding chamber; and at least one processing chamber connected to the feeding chamber.

In accordance with another aspect, the present invention provides a vacuum processing apparatus comprising a plurality of vacuum chambers connected to one another to perform a desired process for substrates, wherein at least two of the vacuum chambers are processing chambers vertically stacked and adapted to perform predetermined processes for substrates, respectively.

In accordance with another aspect, the present invention provides a flat-panel display manufacturing apparatus comprising a load lock chamber, a feeding chamber, and a processing chamber, wherein the load lock chamber comprises: an intermediate wall adapted to divide the interior of the load lock chamber into an upper chamber section and a lower chamber section; top and bottom covers respectively constituting a top wall of the upper chamber section and a bottom wall of the lower chamber section, the top and bottom covers being vertically movable; a cover opening/closing unit connected to the top and bottom covers to vertically move the top and bottom covers toward and away from the intermediate wall, and thus, to selectively open and close the upper and lower chamber sections; gate valves respectively arranged between the upper chamber section and the feeding chamber and the lower chamber section and the feeding chamber to selectively communicate the upper and lower chamber sections with the feeding chamber in accordance with the opening and closing of the upper and lower chamber sections; and upper and lower loaders respectively mounted to the top and bottom covers, each of the upper and lower loaders being adapted to store at least one object to be processed.

In accordance with another aspect, the present invention provides a method for processing substrates, using a flat-panel display manufacturing apparatus including a load lock chamber divided into upper and lower chamber sections, and a feeding chamber connected to the load lock chamber, and a processing chamber connected to the feeding chamber, comprising the steps of: A) upwardly moving a top cover separably mounted to the upper chamber section in a state of isolating the upper chamber section and the feeding chamber from each other by a gate valve, thereby opening the upper chamber section; B) loading at least one substrate into an upper substrate loader mounted to a lower surface of the top cover; C) downwardly moving the top cover, thereby closing the upper chamber section; D) operating an exhausting device, thereby establishing a vacuum state in the upper chamber section; E) driving the gate valve, thereby communicating the upper chamber section and the feeding chamber; F) feeding the substrate loaded in the upper substrate loader into the feeding chamber, and loading the fed substrate into the processing chamber; G) downwardly moving the bottom cover in a state of isolating the lower chamber section and the feeding chamber from each other by the gate valve, simultaneously with the communication between the upper chamber section and the feeding section at step E), thereby opening the lower chamber section; H) loading at least one substrate into the upper substrate loader mounted to an upper surface of the bottom cover in the process of feeding the substrate loaded in the upper chamber section into the feeding chamber at step F); I) upwardly moving the bottom cover, thereby closing the lower chamber section; J) operating the exhausting device, thereby establishing a vacuum state in the lower chamber section; K) isolating the upper chamber section and the feeding chamber from each other by the gate valve during execution of step J) for the establishment of the vacuum state in the lower chamber section; L) driving the gate valve, thereby communicating the lower chamber section and the feeding chamber; M) feeding the substrate loaded in the lower substrate loader into the feeding chamber, and loading the fed substrate into the processing chamber; N) loading the substrate completely processed in the processing chamber into the lower substrate loader; O) upwardly moving the top cover in a state of isolating the upper chamber section and the feeding chamber from each other by the gate valve, simultaneously with the communication between the lower chamber section and the feeding section at step L), thereby opening the upper chamber section; and P) loading at least one substrate into the lower substrate loader in the process of feeding the substrate loaded in the lower chamber section into the feeding chamber at step F) and loading the processed substrate into the lower substrate loader at step N).

### BRIEF DESCRIPTION OF THE DRAWINGS

The above objects, and other features and advantages of the present invention will become more apparent after reading the following detailed description when taken in conjunction with the drawings, in which:

FIG. 1 is a sectional view illustrating a configuration of a conventional FPD manufacturing apparatus;

FIG. 2 is a plan view illustrating a configuration of an FPD manufacturing apparatus according to a first embodiment of the present invention;

FIGS. 3 to 5 are sectional views illustrating the configuration of the FPD manufacturing apparatus according to the first embodiment of the present invention, respectively;

FIG. 6 is a sectional view illustrating a structure of a load lock chamber according to the present invention;

FIG. 7 is a sectional view illustrating an FPD manufacturing apparatus according to a second embodiment of the present invention;

FIG. 8 is a sectional view illustrating another FPD manufacturing apparatus according to the second embodiment of the present invention;

FIG. 9 is a sectional view illustrating a structure of a stacked processing chamber according to the second embodiment of the present invention;

FIG. 10 is a sectional view illustrating an opened state of the stacked processing chamber according to the second embodiment of the present invention;

FIG. 11 is a sectional view illustrating operation of a feeding robot according to the second embodiment of the present invention;

FIG. 12 is a sectional view illustrating a structure of a load lock chamber according to a third embodiment of the present invention;

FIG. 13 is a sectional view illustrating a configuration of an FPD manufacturing apparatus according to the third embodiment of the present invention, taken in a direction different from that of FIG. 13; and

FIGS. 14a to 14c are sectional view explaining a method for processing substrates by use of the FPD manufacturing apparatus according to the third embodiment of the present invention, respectively.

### DESCRIPTION OF THE PREFERRED EMBODIMENTS

Hereinafter, exemplary embodiments of the present invention will be described with reference to the annexed drawings.

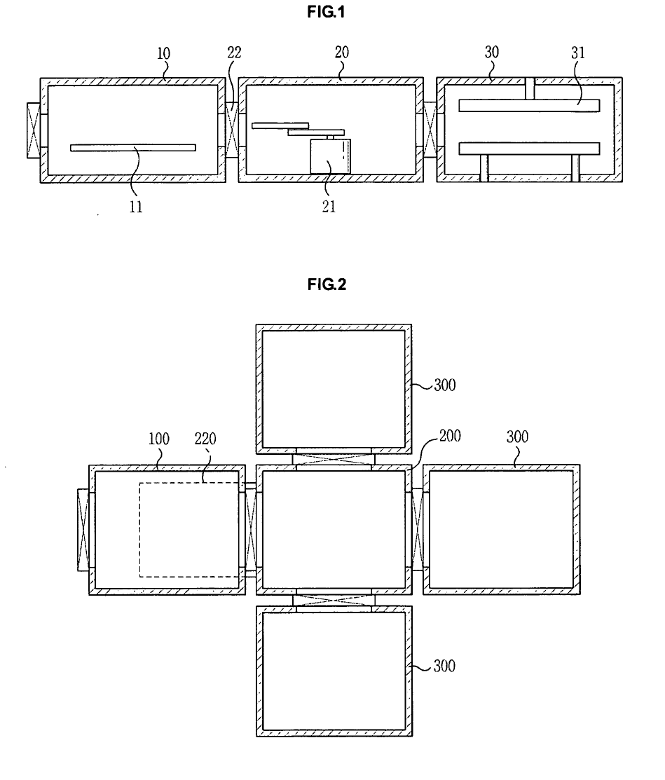

Referring to FIG. 2, an FPD manufacturing apparatus according to a first embodiment of the present invention is illustrated. As shown in FIG. 2, the FPD manufacturing apparatus includes a load lock chamber 100, a feeding chamber 200, and at least one processing chamber 300. In the illustrated case, three processing chambers 300 are arranged around the feeding chamber 200.

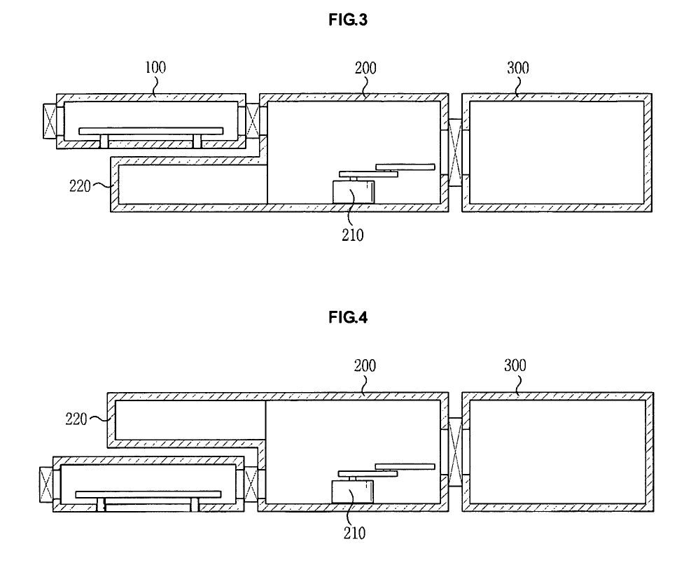

In particular, as shown in FIG. 3, the FPD manufacturing apparatus according to the first embodiment of the present invention includes a temporary substrate storing space 220 to temporarily store a substrate in a desired portion of the feeding chamber 200. The temporary substrate storing space 220 temporarily stores a substrate to be processed in the feeding chamber 300 or a substrate already processed in the processing chamber 300. Practically, several new substrates are stored in the temporary substrate storing space 220 while a desired process is carried out for a substrate in the processing chamber 300. When the process carried out in the processing chamber 300 is completed, the processed substrate is unloaded from the processing chamber 300, and is then stored in the temporary substrate storing space 220. Thereafter, one of the new substrates stored in the temporary substrate storing space 220 is loaded into the processing chamber 300, and a new process is carried out for the loaded substrate. Thus, the loading of a substrate to be processed in the processing chamber 300 is achieved by loading, into the processing chamber 300, one of the substrates stored in the temporary substrate storing space 220 without directly loading a new substrate from an external station into the processing chamber 300.

The temporary substrate storing space 220 is communicated with the interior of the feeding chamber 200, so that the temporary substrate storing space 220 is maintained in a vacuum state or in an atmospheric state in accordance with the vacuum or atmospheric state of the feeding chamber 200. Accordingly, it is unnecessary to install a separate vacuum establishing device in the temporary substrate storing space 220.

When a predetermined number of processed substrates are stored in the temporary substrate storing space 220 after repeated execution of the substrate processing in the processing chamber 300, the processed substrates are outwardly unloaded via the load lock chamber 100 at one time. Thereafter, a plurality of new substrates are loaded from the external station into the temporary substrate storing space 220 at one time via the load lock chamber 100. Accordingly, it is possible to reduce the time taken to perform loading and unloading of substrates, as compared to the case in which the substrate loading and unloading operations are sequentially carried out for respective substrates. It is also possible to reduce the number of operations to establish vacuum in the load lock chamber 100, for example, pumping operations, so that the process for processing substrates is simplified, thereby achieving an enhancement in process efficiency.

In particular, the temporary substrate storing space 220 can be more advantageously used where a plurality of processing chambers 330 are connected to one feeding chamber 200 such that the processing chambers 330 perform the same process or sequentially perform different processes, that is, where a plurality of substrates loaded at one time are simultaneously processed.

A substrate storing die (not shown) is arranged in the temporary substrate storing space 220. Preferably, the substrate storing die has a plurality of substrate support surfaces to simultaneously store a plurality of substrates.

In place of using the substrate support surfaces to store a plurality of substrates, another method may be used, in which a substrate storing box capable of simultaneously storing a plurality of substrates in a stacked state is loaded from an external station into the temporary substrate storing space 220. For example, a cassette, which is a substrate storing box capable of simultaneously storing several substrates, is inserted into the feeding chamber 200 such that the cassette is loaded on the substrate storing die. In this case, accordingly, the substrate storing die can support a plurality of substrates without employing the substrate support surfaces.

A gate valve (not shown) may be arranged at an inlet of the temporary substrate storing space 220, in order to isolate the temporary substrate storing space 220 from the feeding chamber 200. In this case, it is unnecessary to use a separate vacuum establishing device for independently establishing a vacuum atmosphere in the temporary substrate storing space 220. This is because the temporary substrate storing space 220 is maintained in a vacuum state, similarly to the feeding chamber 200.

The temporary substrate storing space 220 may be arranged at the side of the feeding chamber 220 where the load lock chamber 100 is arranged, such that the temporary substrate storing space 220 and load lock chamber 100 are vertically stacked, as shown in FIG. 2. That is, when viewing from the top of the FPD manufacturing apparatus, the load lock chamber 100 and temporary substrate storing space 220 completely overlap with each other. In this case, there is an advantage in that it is possible to feed a substrate, only using horizontal and vertical movements of a feeding robot 210 arranged in the feeding chamber 200, without using rotation of the feeding robot 210. Also, it is possible to arrange an increased number of feeding chambers 330 around the feeding chamber 200 because the area occupied by the load lock chamber 100 and temporary substrate storing space 220 is reduced.

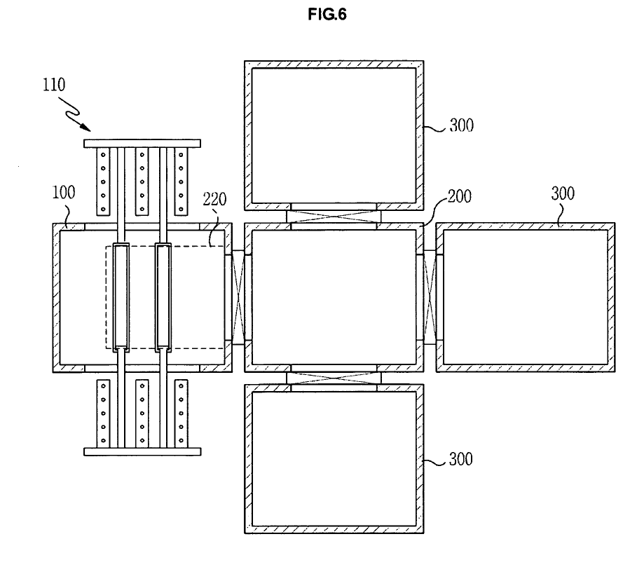

The temporary substrate storing space 220 may be arranged such that it partially overlaps with the load lock chamber 100, as shown in FIG. 5. That is, the load lock chamber 100 and temporary substrate storing space 220 may not completely overlap with each other, but may partially overlap with each other, when viewing the top of the FPD manufacturing apparatus. In this case, there is an advantage in that, although the area occupied by the load lock chamber 100 and temporary substrate storing space 220 increases slightly, the height of the apparatus can be reduced, as compared to the case in which the load lock chamber 100 and temporary substrate storing space 220 completely overlap with each other. Accordingly, there are additional advantages in that it is possible to easily manufacture and repair the FPD manufacturing apparatus.

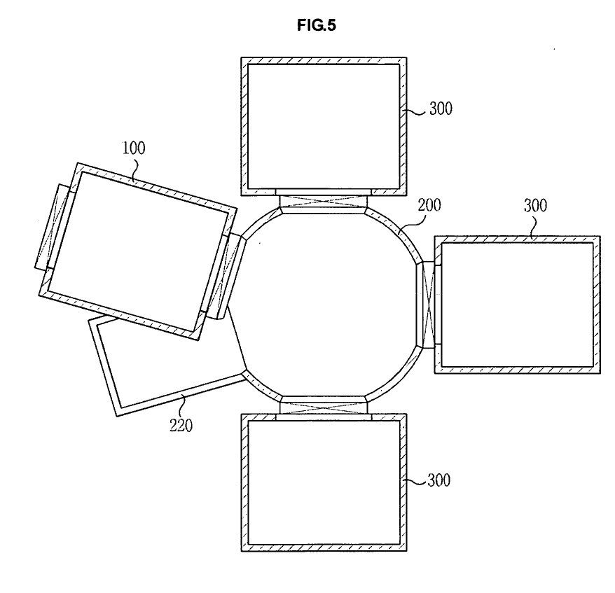

The vertical positions of the load lock chamber 100 and temporary substrate storing space 220 may be varied, as shown in FIGS. 3 and 4. That is, as shown in FIG. 3, the load lock chamber 100 may be arranged at a lower position, whereas the temporary substrate storing space 220 may be arranged at an upper position. Also, the load lock chamber 100 and temporary substrate storing space 220 may be arranged at positions reverse to those of FIG. 3, respectively, as shown in FIG. 4.

Preferably, the temporary substrate storing space 220 is separably coupled to the feeding chamber 200. Where the temporary substrate storing space 220 has a structure capable of being separably coupled to the feeding chamber 200, it is possible to easily repair the interior of the temporary substrate storing space 220 because the repair process can be carried out under the condition in which the temporary substrate storing space 220 is separated from the feeding chamber 200.

Preferably, as shown in FIG. 6, the load lock chamber 100 includes openings (not shown) respectively formed through the opposite side walls of the load lock chamber 100 arranged adjacent to the side wall of the load lock chamber 100 connected to the feeding chamber 200, to allow substrates to pass through the openings for loading and unloading of the substrates, doors (not shown) respectively adapted to open/close the openings, and substrate loading/unloading units 110 respectively adapted to perform the loading and unloading of the substrates through the openings in a state of supporting the substrates. In accordance with this substrate loading/unloading arrangement, it is possible to greatly reduce the time taken to load/unload substrates because the substrate loading/unloading units 110 individually carry out substrate loading and unloading operations. The substrate loading/unloading arrangement may be provided at only one of the opposite side walls of the load lock chamber 100 arranged adjacent to the side wall of the load lock chamber 100 connected to the feeding chamber 200.

Hereinafter, substrate loading and unloading procedures carried out by the FPD manufacturing apparatus according to this embodiment will be described in detail.

First, the substrate loading and unloading procedures will be described in conjunction with the case in which the FPD manufacturing apparatus includes a gate valve arranged at the side wall of the load lock chamber 100 opposite to the side wall of the load lock chamber 100 connected to the feeding chamber 100, for loading and unloading of substrates, as shown in FIG. 2.

When three substrates are supplied from the external station into the load lock chamber 100 through the gate valve arranged at the side wall of the load lock chamber 100 opposite to the side wall of the load lock chamber 100 connected to the feeding chamber 100, the feeding robot arranged in the feeding chamber 200 loads the three substrates, one by one, into respective processing chambers 300. Thereafter, three new substrates are supplied from the external station into the load lock chamber 100, and are maintained in a loaded state in the load lock chamber 100 while a desired process is carried out in the processing chambers 300. After completion of the process carried out in the processing chambers 300, gate valves, each of which is arranged between the feeding chamber 200 and an associated one of the processing chambers 300, are opened. The completely-processed substrates are then unloaded from the processing chambers 300, and are stored in the temporary substrate storing space 220.

Subsequently, the three new substrates loaded in the load lock chamber 100 are loaded, one by one, into respective processing chambers 300. The gate valves each arranged between the feeding chamber 200 and the associated processing chamber 300 are closed. Thereafter, the processed substrates stored in the temporary substrate storing space 220 are externally unloaded via the load lock chamber 100. Three new substrates to be processed are then loaded into the load lock chamber 100.

As described above, in accordance with this embodiment, a plurality of processing chambers are arranged around the feeding chamber so that, where it is desired to simultaneously process a plurality of substrates in respective processing chambers, the loading and unloading of the substrates are carried out simultaneously for all processing chambers, without being sequentially carried out for respective processing chambers. Accordingly, it is possible to greatly reduce the time taken to load/unload substrates.

Next, the substrate loading and unloading procedures will be described in conjunction with the case in which the FPD manufacturing apparatus includes substrate loading/unloading arrangements each including one opening, one door, and one substrate loading/unloading unit 110, for loading and unloading of substrates through the opposite side walls of the load lock chamber 100 arranged adjacent to the side wall of the load lock chamber 100 connected to the feeding chamber 200.

Substrates are supplied to each substrate loading/unloading unit 110 by a conveyor (not shown) arranged along the opposite side walls of the load lock chamber 100 where the substrate loading/unloading arrangements are arranged. Substrates, which have been completely processed, are transferred from the substrate loading/unloading units 110 to the conveyor.

In this case, the loading and unloading of substrates can be more efficiently achieved because the loading and unloading of substrates are carried out at both sides of the load lock chamber 100. The remaining substrate loading and unloading operations are carried out in the same manner as in the case in which the FPD manufacturing apparatus includes the gate valve arranged at the side wall of the load lock chamber 100 opposite to the side wall of the load lock chamber 100 connected to the feeding chamber 100, for loading and unloading of substrates. Accordingly, no further description will be given.

Hereinafter, an FPD manufacturing apparatus according to a second embodiment of the present invention will be described.

The second embodiment provides an FPD manufacturing apparatus comprising a plurality of vacuum chambers connected to one another to perform a desired process for substrates, wherein at least two of the vacuum chambers are processing chambers vertically stacked and adapted to perform predetermined processes for substrates, respectively.

The second embodiment also provides a vacuum processing apparatus comprising a plurality of vacuum chambers including load lock chambers, feeding chambers, and processing chambers, which are connected to one another to perform a desired process for substrates, wherein at least two of the processing chambers, which are adapted to perform a desired process for substrates, are vertically stacked.

The FPD manufacturing apparatus according to the second embodiment includes a plurality of vacuum chambers including load lock chambers, feeding chambers, and processing chambers, which are connected to one another to perform a desired process for substrates, as in the case of FIG. 1. The FPD manufacturing apparatus of the second embodiment is characterized in that at least two of the vacuum chambers are vertically stacked. In this case, accordingly, the FPD manufacturing apparatus can occupy a reduced area in a clean room while processing an increased number of substrates, and thus, achieves an enhancement in substrate processing efficiency.

In particular, in the FPD manufacturing apparatus of the second embodiment, the load lock chambers, which have the same inner configuration and the same function, have a single-layer arrangement, and the feeding chambers, which have the same inner configuration and the same function, have a single-layer arrangement, whereas the processing chambers have a vertically-stacked or multi-layer arrangement.

Since much time is taken for the process carried out in the processing chambers, as compared to those in other vacuum chambers, it is desirable to drive the load lock chambers and feeding chambers, to unload a substrate completely processed in one processing chamber, and to load a new substrate in the processing chamber while a desired process is carried out in another processing chamber so that the substrate processing carried out between the processing chambers is efficiently achieved.

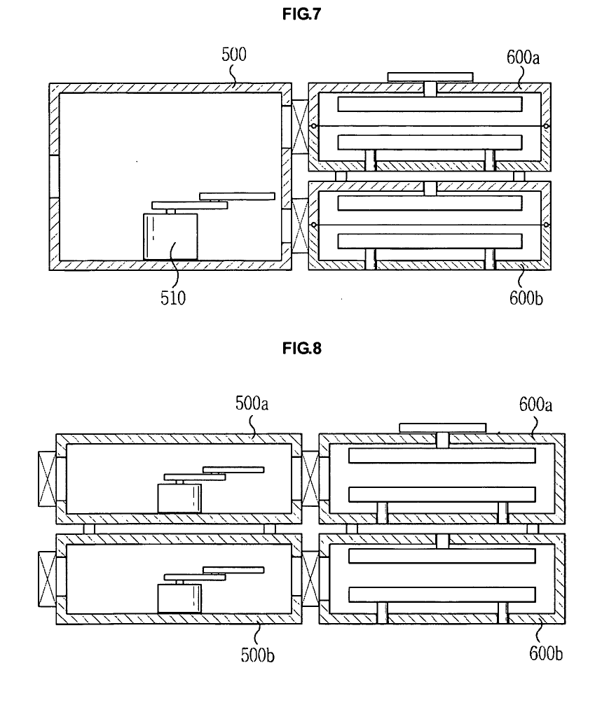

Preferably, the number of the vertically-stacked processing chambers is two, as shown in FIG. 7. The two processing chambers may perform the same function or may perform different functions, respectively.

In particular, where the FPD manufacturing apparatus is a dry etching device, it is preferred that each of the two processing chambers be a plasma enhanced etching (PE) type dry etching chamber or a reactive ion etching (RIE) type dry etching chamber, or the two processing chambers are a PE type dry etching chamber and an RIE type dry etching chamber, respectively. That is, both the processing chambers may be PE type dry etching chambers or RIE type dry etching chambers so that the processing chambers perform the same function. Alternatively, the processing chambers may be a PE type dry etching chamber and an RIE type dry etching chamber, respectively, so that the processing chambers perform different functions, respectively.

Where the vertically-stacked processing chambers have different functions, respectively, there is an advantage in that the different functions can be carried out, using one vacuum processing apparatus, so that it is unnecessary to employ an additional vacuum processing apparatus.

Also, where the vertically-stacked processing chambers have the same function, there is an advantage in that substrate loading and unloading operations are carried out for one processing chamber while a desired process is carried out in the other processing chamber, so that the substrate processing efficiency of the vacuum type processing device is increased.

In the vertically-stacked processing chamber arrangement, it is preferred that an upper one of the processing chambers, that is, a processing chamber 600a, be a PE type dry etching chamber, and a lower one of the processing chambers, that is, a processing chamber 600b, be an RIE type dry etching chamber.

In this case, there is an advantage in that the overall height of the processing chamber arrangement is lower than those of other processing chamber arrangements because RE power is applied to an upper electrode in the case of a PE type dry etching chamber whereas RE power is applied to a lower electrode in the case of an RIE type dry etching chamber, so that it is unnecessary to arrange installations between the processing chambers.

Meanwhile, it is necessary to perform maintenance and repair for the inner structures of the upper and lower processing chambers in the vertically-stacked processing chamber arrangement. Accordingly, each processing chamber must have an openable structure.

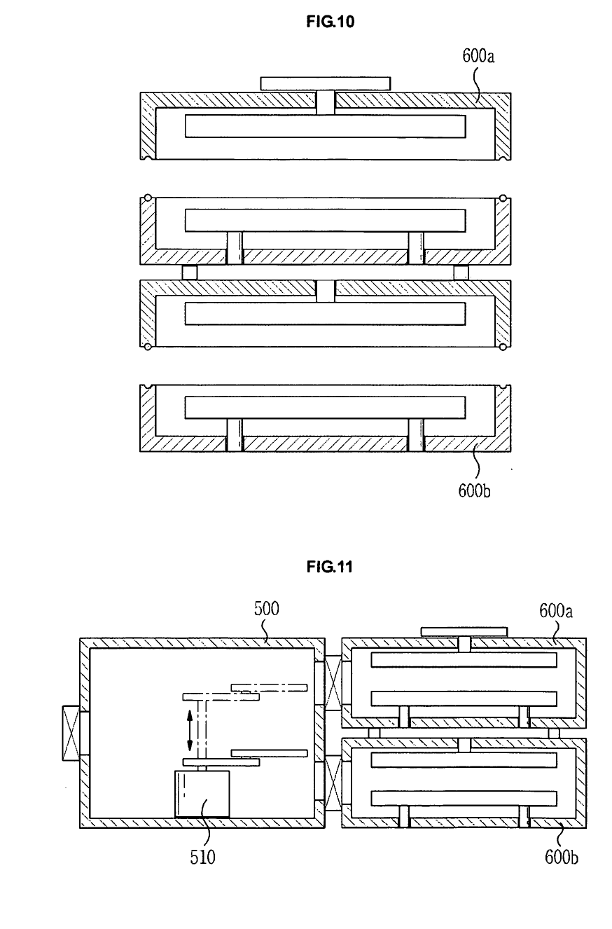

To this end, in accordance with this embodiment, each of the processing chambers 600a and 600b has a vertically-separable structure, as shown in FIG. 9. Preferably, the upper processing chamber 600a has a structure in which an upper portion of the upper processing chamber 600a is vertically movable to open and close the upper processing chamber 600a, and the lower processing chamber 600b has a structure in which a lower portion of the upper processing chamber 600a is vertically movable to open and close the lower processing chamber 600a, as shown in FIG. 10, so that it is possible to conveniently perform maintenance and repair for the interior of each processing chamber 600a or 600b.

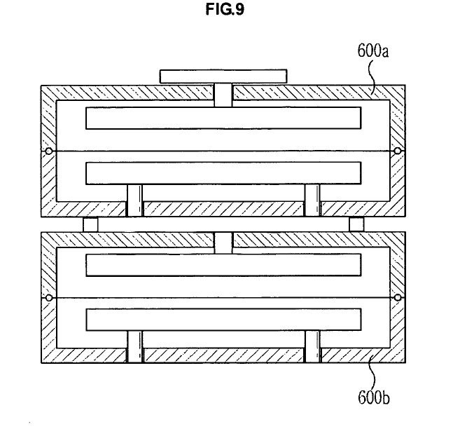

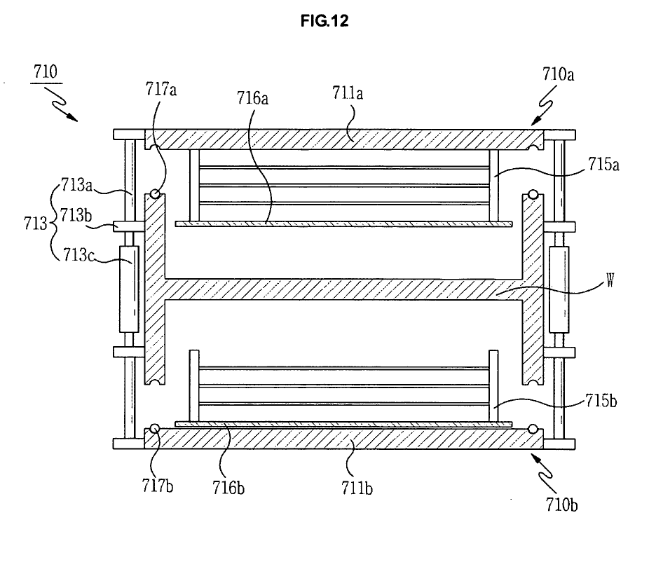

The FPD manufacturing apparatus may include a single feeding chamber arranged adjacent to the vertically-stacked processing chamber, as shown in FIG. 7. Alternatively, the FPD manufacturing apparatus may include a plurality of vertically-stacked feeding chambers, as shown in FIG. 8.

Where a single feeding chamber is used, as shown in FIG. 7, it is necessary to use a feeding robot 510, which is vertically movable, as shown in FIG. 11, in order to feed substrates to both the upper and lower processing chambers, respectively.

Next, an FPD manufacturing apparatus according to a third embodiment of the present invention will be described.

The third embodiment of the present invention provides an FPD manufacturing apparatus comprising a load lock chamber, a feeding chamber, and a processing chamber, wherein the load lock chamber comprises: an intermediate wall adapted to divide the interior of the load lock chamber into an upper chamber section and a lower chamber section; top and bottom covers respectively constituting a top wall of the upper chamber section and a bottom wall of the lower chamber section, the top and bottom covers being vertically movable; a cover opening/closing unit connected to the top and bottom covers to vertically move the top and bottom covers toward and away from the intermediate wall, and thus, to selectively open and close the upper and lower chamber sections; gate valves respectively arranged between the upper chamber section and the feeding chamber and the lower chamber section and the feeding chamber to selectively communicate the upper and lower chamber sections with the feeding chamber in accordance with the opening and closing of the upper and lower chamber sections; and upper and lower loaders respectively mounted to the top and bottom covers, each of the upper and lower loaders being adapted to store at least one object to be processed.

In accordance with the third embodiment of the present invention, an exhausting device and a gas supplier are installed in each of the upper and lower chamber sections, so that the upper and lower chamber sections can establish a vacuum state and an atmospheric state independently of each other. Accordingly, it is possible to efficiently achieve loading and unloading of substrates carried out by the load lock chamber.

In accordance with the third embodiment of the present invention, the cover opening/closing unit comprises a movable shaft coupled to the top cover or bottom cover, a guide member adapted to guide movement of the movable shaft, and a driver coupled to the movable shaft to vertically move the movable shaft. In accordance with this configuration of the cover opening/closing unit, it is possible to easily open and close the top and bottom covers. Using the cover opening/closing unit, the top and bottom covers can be alternately opened and closed.

The FPD manufacturing apparatus according to the third embodiment of the present invention may further comprise a first bottom plate, which is provided at a lower end of the upper loader, and has an area larger than that of the object to be stored in the upper loader. Using the first bottom plate, it is possible to easily remove substrate fragments generated due to damage of substrates occurring during loading and unloading of the substrates.

The FPD manufacturing apparatus according to the third embodiment of the present invention may further comprise a second bottom plate, which is provided at a lower end of the lower loader, and has an area larger than that of the object to be stored in the lower loader.

The FPD manufacturing apparatus according to the third embodiment of the present invention may further comprise a controller adapted to control the gate valves to isolate the upper chamber section and the feeding chamber from each other and to communicate the lower chamber section and the feeding chamber with each other when the top cover is vertically moved to open the upper chamber section, and to control the gate valves to isolate the lower chamber section and the feeding chamber from each other and to communicate the upper chamber section and the feeding chamber with each other when the bottom cover is vertically moved to open the lower chamber section. Accordingly, the FPD manufacturing apparatus can efficiently operate.

The third embodiment of the present invention also provides a method for processing substrates, using an FPD manufacturing apparatus including a load lock chamber divided into upper and lower chamber sections, and a feeding chamber connected to the load lock chamber, and a processing chamber connected to the feeding chamber, comprising the steps of:

A) upwardly moving a top cover separably mounted to the upper chamber section in a state of isolating the upper chamber section and the feeding chamber from each other by a gate valve, thereby opening the upper chamber section;

B) loading at least one substrate into an upper substrate loader mounted to a lower surface of the top cover;

C) downwardly moving the top cover, thereby closing the upper chamber section;

D) operating an exhausting device, thereby establishing a vacuum state in the upper chamber section;

E) driving the gate valve, thereby communicating the upper chamber section and the feeding chamber;

F) feeding the substrate loaded in the upper substrate loader into the feeding chamber, and loading the fed substrate into the processing chamber;

G) downwardly moving the bottom cover in a state of isolating the lower chamber section and the feeding chamber from each other by the gate valve, simultaneously with the communication between the upper chamber section and the feeding section at step E), thereby opening the lower chamber section;

H) loading at least one substrate into the upper substrate loader mounted to an upper surface of the bottom cover in the process of feeding the substrate loaded in the upper chamber section into the feeding chamber at step F);

I) upwardly moving the bottom cover, thereby closing the lower chamber section;

J) operating the exhausting device, thereby establishing a vacuum state in the lower chamber section;

K) isolating the upper chamber section and the feeding chamber from each other by the gate valve during execution of step J) for the establishment of the vacuum state in the lower chamber section;

L) driving the gate valve, thereby communicating the lower chamber section and the feeding chamber;

M) feeding the substrate loaded in the lower substrate loader into the feeding chamber, and loading the fed substrate into the processing chamber;

N) loading the substrate completely processed in the processing chamber into the lower substrate loader;

O) upwardly moving the top cover in a state of isolating the upper chamber section and the feeding chamber from each other by the gate valve, simultaneously with the communication between the lower chamber section and the feeding section at step L), thereby opening the upper chamber section; and

P) loading at least one substrate into the lower substrate loader in the process of feeding the substrate loaded in the lower chamber section into the feeding chamber at step F) and loading the processed substrate into the lower substrate loader at step N).

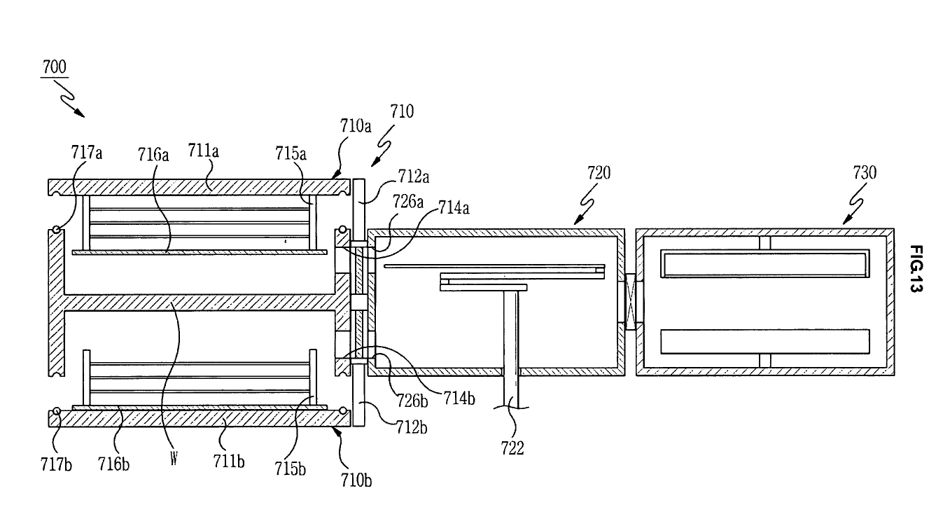

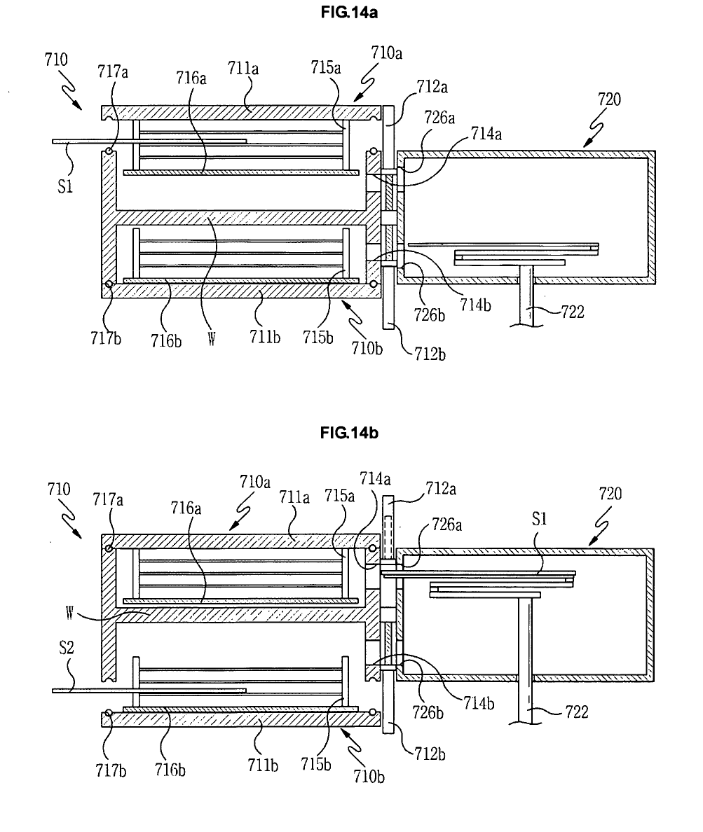

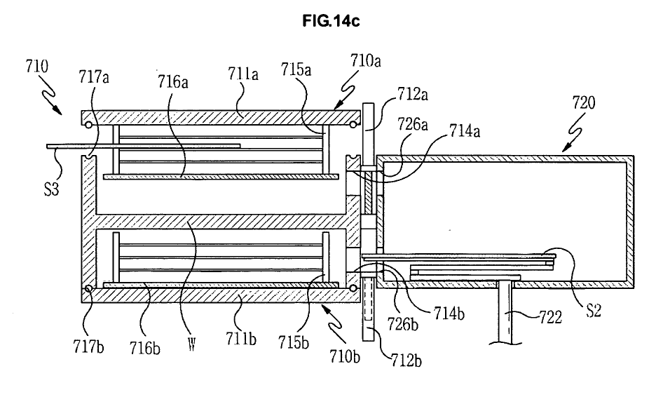

Hereinafter, the third embodiment of the present invention will be described in detail with reference to FIG. 12, FIG. 13, and FIGS. 14a to 14c.

As shown in FIG. 12, the FPD manufacturing apparatus according to the third embodiment, which is designated by reference numeral 700, includes a load lock chamber 710, a feeding chamber 720, and a processing chamber 730. Each of the feeding chamber 720 and processing chamber 730 has the same structure and function as those of the above-mentioned conventional FPD manufacturing apparatus, so that no further description will be given of the feeding chamber 720 and processing chamber 730.

In accordance with the third embodiment, the load lock chamber 710 includes an intermediate wall W, a top cover 711a, a bottom cover 711b, gate valves 721a and 712b, and cover opening/closing units 713.

The intermediate wall W is horizontally arranged at a central portion of the load lock chamber 710 to divide the interior of the load lock chamber 710 into an upper chamber section 710a and a lower chamber section 710b. Thus, the upper and lower chamber sections 710a and 710b of the load lock chamber 710, isolated from each other by the intermediate wall W, can operate independently of each other.

Where the load lock chamber 710 is divided into the upper and lower chamber sections 710a and 710b, as described above, it is possible to independently perform loading and unloading of substrates for respective chamber sections 710a and 710b, and thus, to achieve an enhancement in substrate loading/unloading efficiency.

The top cover 711a is arranged on the upper chamber section 710a. In detail, the top cover 711a is mounted to an upper end of the upper chamber section 710a to constitute a top wall of the upper chamber section 710a. As shown in FIG. 12, the top cover 711a is upwardly movable from the upper chamber section 710a to upwardly open the upper chamber section 710a. Accordingly, when it is desired to load a substrate from an external station into the upper chamber section 710a of the load lock chamber 710 or to externally unload the substrate from the upper chamber section 710a, the loading and unloading of the substrate can be achieved by upwardly moving the top cover 711a, thereby opening the upper chamber section 710a, and performing loading and unloading of the substrate through the opened upper chamber section 710a by use of an external robot (not shown) arranged adjacent to the load lock chamber 710.

The bottom cover 711b is arranged on the lower chamber section 710b. In detail, the bottom cover 711b is mounted to a lower end of the lower chamber section 710b to constitute a bottom wall of the lower chamber section 710b. As shown in FIG. 12, the bottom cover 711b is downwardly movable from the lower chamber section 710b to downwardly open the lower chamber section 710b.

As shown in FIG. 13, openings 714a and 714b are formed through the side wall of the load lock chamber 710 contacting the feeding chamber 720 at regions corresponding to the upper and lower chamber sections 710a and 710b, respectively. The openings 714a and 714b function as gateways, through which substrates and a feeding robot 722 pass for transfer of substrates between the load lock chamber 710 and the feeding chamber 720. Accordingly, the openings 714a and 714b have a size capable of allowing the substrates and feeding robot 722 to pass through the openings 714a and 714b. The feeding chamber 720 is also provided with openings 726a and 726b having the same size as the openings 714a and 714b at regions corresponding to the openings 714a and 714b, respectively.

Each of the openings 714a and 714b formed at the load lock chamber 710 is spaced apart from an associated one of the openings 726a and 726b formed at the feeding chamber 720 by a predetermined distance.

Gate valves 712a and 712b are interposed between the upper chamber section 710a and the feeding chamber 720 and between the lower chamber section 710b and the feeding chambers 720, respectively. The gate valve 712a functions to open/close the opening 714a of the upper chamber section 710a and the opening 726a of the feeding chamber 720, and the gate valve 712b functions to open/close the opening 714b of the lower chamber section 710b and the opening 726b of the feeding chamber 720. The gate valves 712a and 712b must operate independently of each other. In order to use the upper and lower chamber sections 710a and 710b independently of each other, it is necessary to open/close the upper and lower openings 714a and 714b. To this end, the gate valves 712a and 712b must operate independently of each other.

The cover opening/closing units 713 are arranged at opposite side walls of the load lock chamber 710, respectively, to open/close the top and bottom covers 711a and 711b. Each cover opening/closing unit 713 must have a configuration capable of opening/closing the top and bottom covers 711a and 711b independently of each other.

In accordance with the third embodiment, as shown in FIG. 12, each cover opening/closing unit 713 includes a reciprocating shaft 713a, a guide member 713b, and a power generator 713c, in order to vertically move the top cover 711a. The movable shaft 713a is vertically movable to vertically move the top cover 711a, and thus, to open/close the top cover 711a. The movable shaft 713a is mounted, at an upper end thereof, to an associated one of the opposite lateral ends of the top cover 711a, and is coupled, at a lower end thereof, to the power generator 713c. The power generator 713c may be a motor, and the movable shaft 713a may have a cylinder structure so that the movable shaft 713a is vertically movable in accordance with rotation of the motor.

The guide member 713b is mounted to an associated one of the opposite side walls of the load lock chamber 710 to guide movement of the movable shaft 713a. The guide member 713b has a through hole, through which the movable shaft 713a extends. The movable shaft 713a also functions to distribute the weight of the top cover 711a applied to the power generator 713c.

The power generator 713c generates power to vertically move the movable shaft 713a. The power generator 713c is fixedly mounted to the associated side wall of the load lock chamber 710, and is coupled with the lower end of the movable shaft 713a.

Each cover opening/closing unit 713 also includes another reciprocating shaft 713a, another guide member 713b, and another power generator 713c, in order to vertically move the bottom cover 711b. The power generator 713c for the bottom cover 711b may be dispensed with. In this case, the power generator 713c for the top cover 711b functions to move both the movable shaft 713a connected to the top cover 711a and the movable shaft 713a connected to the bottom cover 711b.

Upper and lower substrate loaders 715a and 715b are provided at the top cover 711a and bottom cover 711b, respectively. The upper substrate loader 715a is mounted to a lower surface of the top cover 711a. Preferably, the upper substrate loader 715a has a structure capable of storing a plurality of substrates. The lower substrate loader 715b has the same structure as the upper substrate loader 715a, and is mounted to an upper surface of the bottom cover 711b.

Preferably, bottom plates 716a and 716b are provided at the upper and lower substrate loaders 715a and 715b, respectively. The bottom plates 716a and 716b have an area larger than those of substrates to be stored in the upper and lower substrate loaders 715a and 715b, so that substrate fragments possibly generated due to damage of one or more of the substrates stored in the upper and lower substrate loaders 715a and 715b can be prevented from falling into the load lock chamber 710. That is, such fragments are completely collected on the bottom plate 716a or 716b without falling into the load lock chamber 710 because the bottom plates 716a and 716b have a wide plate structure having an area larger than those of substrates to be stored in the upper and lower substrate loaders 715a and 715b. The collected substrate fragments can be easily removed by upwardly moving the top cover 711a or downwardly moving the bottom cover 711b, and thus, externally exposing the bottom plate 716a or 716b.

An exhausting device (not shown) and a gas supplier (not shown) are installed in the upper chamber section 710a in accordance with the third embodiment. The exhausting device sucks gas present in the upper chamber section 710a, and outwardly discharges the sucked gas, thereby establishing a vacuum state in the upper chamber section 710a. The gas supplier supplies gas such as nitrogen into the upper chamber section 710a, thereby establishing an atmospheric state in the upper chamber section 710a. Also, another exhausting device and another gas supplier, which have the same functions as those of the upper chamber section 710a, are installed in the lower chamber section 710b. Accordingly, the upper and lower chamber sections 710a and 710b can establish vacuum and atmospheric states independently of each other.

Only under the condition in which the upper and lower chamber sections 710a and 710b operate independently of each other, each of the upper and lower chamber sections 710a and 710b can function as an independent load lock chamber.

A seal member fitting groove is formed at a peripheral portion of the top cover 711a. A seal member 717a is arranged along the upper ends of the side walls of the load lock chamber 710. Another seal member fitting groove is formed along the lower ends of the side walls of the load lock chamber 710. Another seal member 717b is arranged along a peripheral portion of the bottom cover 711b. In accordance with these configurations, it is possible to isolate the upper or lower chamber section 710a or 710b of the load lock chamber 710 from the outside in the closed state of the upper or lower cover 711a or 711b, and thus, to establish a vacuum state in the upper or lower chamber section 710a or 710b.

The FPD manufacturing apparatus 700 according to the third embodiment further includes a controller. The controller controls the gate valve 712a to isolate the upper chamber section 710a and feeding chamber 720 from each other when the top cover 711a is upwardly moved to open the upper chamber section 710a. The controller also controls the gate valve 712b to isolate the lower chamber section 710b and feeding chamber 720 from each other when the bottom cover 711b is downwardly moved to open the lower chamber section 710b.

Thus, the upper and lower chamber sections 710a and 710b operate independently from each other, so that it is possible to efficiently load and unload substrates.

Hereinafter, the method for processing substrates, using the FPD manufacturing apparatus 700 according to the third embodiment will be described with reference to FIGS. 14a to 14c.

First, the top cover 711a is upwardly moved to open the upper chamber section 710a, as shown in FIG. 14a. At this time, the opening 714a of the upper chamber section 710a and the opening 726a of the feeding chamber 720 are maintained in a closed state by the gate valve 712a. Accordingly, although the upper chamber section 710a is in an atmospheric state, the feeding chamber 720 is maintained in a vacuum state.

In the opened state of the upper chamber section 710a, a first substrate S1 is loaded into the upper substrate loader 715a by the external robot (not shown) arranged near the load lock chamber 710. At this time, several substrates may be loaded in the upper substrate loader 715a.

After the loading of the first substrate S1, the top cover 711a is downwardly moved to close the top cover 711a. Thus, the interior of the upper chamber section 710a is sealed. In this state, the exhausting device for the upper chamber section 710a is driven to exhaust gas from the upper chamber section 710a, thereby establishing a vacuum state in the upper chamber section 710a. When the upper chamber section 710a reaches the same vacuum level as that of the feeding chamber 720, the gate valve 712a, which isolates the upper chamber section 710a and feeding chamber 720 from each other, is opened.

When the gate valve 712a is opened, the feeding robot 722 arranged in the feeding chamber 720 feeds the first substrate S1 loaded in the upper substrate loader 715a into the feeding chamber 720 through the openings 714a and 726a, as shown in FIG. 14b. After the feeding of the first substrate S1 into the feeding chamber 720, the upper chamber section 710a and feeding chamber 720 are again isolated from each other by the gate valve 712a. In this state, the feeding robot 722 feeds the first substrate S1 into the processing chamber 730.

In the process of loading the first substrate S1 from the upper chamber section 710a into the feeding chamber 720, a second substrate S2 is loaded into the lower chamber section 710b. That is, when the top cover 711a is closed, the bottom cover 711b is downwardly moved to open the lower chamber section 710b, as shown in FIG. 14b. At this time, the lower chamber section 710b and feeding chamber 720 are maintained in a state of being isolated from each other by the gate valve 712b. In this state, the external robot loads the second substrate S2 into the lower substrate loader 715b. After the loading of the second substrate S2, the bottom cover 711b is upwardly moved to close the bottom cover 711b. In this state, the lower chamber section 710a is exhausted.

After completion of the exhaustion of the lower chamber section 710b, the gate valve 712b is opened to communicate the lower chamber section 710b and feeding chamber 720. In this state, the substrate S2 is fed into the feeding chamber 720 by the feeding robot 722.

Accordingly, the substrate loaded in the lower chamber section 710b is fed into the feeding chamber 720 in the process of loading the substrate supplied from the external station into the upper chamber section 710a, as shown in FIG. 14c, and the substrate loaded in the upper chamber section 710a is fed into the feeding chamber 720 in the process of loading the substrate supplied from the external station into the lower chamber section 710b, as shown in FIG. 14b. Thus, the substrates loaded in the upper and lower chamber sections 710a and 710b are alternately fed into the feeding chamber 720.

In accordance with the FPD manufacturing apparatus of the present invention, it is possible to greatly reduce the time taken to load/unload substrates, and thus, to reduce the time taken to process large-size substrates. Accordingly, there is an advantage of an enhancement in substrate processing efficiency.

In accordance with the FPD manufacturing apparatus of the present invention, a substrate is loaded into the processing chamber after another substrate, which has been processed, is loaded in a separate space. Accordingly, it is possible to prevent particles possibly generated during a substrate feeding procedure carried out in the feeding chamber from falling on the processed substrate, and thus, to prevent the substrate from being damaged.

In accordance with the present invention, it is possible to achieve an enhancement in substrate processing efficiency under the condition in which the area of the clean room where the vacuum processing apparatus is installed is constant.

In particular, the vacuum processing apparatus may include processing chambers arranged in a stacked state, and adapted to perform different processes, respectively. In this case, there is an advantage in that different processes can be simultaneously carried out in one vacuum processing apparatus. Even in the case in which processing chambers arranged in a stacked state have the same function, there is an advantage of a remarkable enhancement in substrate processing efficiency.

In accordance with the present invention, each of the stacked processing chambers has a structure enabling a maintenance and repair process for the interior of the processing chamber in spite of the stacked chamber arrangement. Accordingly, there is an advantage in that the vacuum processing apparatus can be repaired in the same manner as in conventional vacuum processing apparatuses.

In accordance with the present invention, the upper and lower chamber sections of the load lock chamber perform loading and unloading of substrates independently of each other. Accordingly, the operation efficiency of the FPD manufacturing apparatus is enhanced.

In addition, the FPD manufacturing apparatus has the same effect as that of the case in which two load lock chambers are vertically stacked, while having a reduced load lock chamber height, as compared to the case in which two load lock chambers are vertically stacked. Accordingly, there are advantages of an easy installation of the load lock chamber and a reduction in the vertical movement range of the feeding robot.

1. A flat-panel display manufacturing apparatus comprising a load lock chamber and a feeding chamber connected to the load lock chamber, the apparatus further comprising:
a temporary substrate storing space arranged at a predetermined portion of the feeding chamber; and
at least one processing chamber connected to the feeding chamber.

2. The flat-panel display manufacturing apparatus according to claim 1, wherein the temporary substrate storing space is arranged at one side wall of the feeding chamber, to which the load lock chamber is connected, such that the temporary substrate storing space and the load lock chamber are stacked while completely overlapping with each other.

3. The flat-panel display manufacturing apparatus according to claim 1, wherein the temporary substrate storing space and the load lock chamber are stacked while partially overlapping with each other.

4. The flat-panel display manufacturing apparatus according to claim 2 or 3, wherein the load lock chamber comprises:
an opening formed through one of opposite side walls of the load lock chamber arranged adjacent to a side wall of the load lock chamber connected to the feeding chamber, to allow a substrate to pass through the opening for loading and unloading of the substrate;
a door adapted to open/close the opening; and
a substrate loading/unloading unit adapted to perform the loading and unloading of the substrate through the opening in a state of supporting the substrate.

5. The flat-panel display manufacturing apparatus according to claim 4, wherein the load lock chamber further comprises:
an additional opening formed through the other one of the opposite side walls of the load lock chamber arranged adjacent to the side wall of the load lock chamber connected to the feeding chamber, to allow a substrate to pass through the additional opening for loading and unloading of the substrate;
an additional door adapted to open/close the opening; and
an additional substrate loading/unloading unit adapted to perform the loading and unloading of the substrate through the opening in a state of supporting the substrate.

6. The flat-panel display manufacturing apparatus according to claim 5, wherein:
the load lock chamber further comprises a conveyor arranged adjacent to the opposite side walls of the load lock chamber to feed substrates; and
the conveyor transfers the fed substrates to the substrate loading/unloading units, respectively, for the loading of the substrates, and receives substrates from the substrate loading/unloading units, for the unloading of the substrates.

7. The flat-panel display manufacturing apparatus according to claim 2 or 3, wherein the temporary substrate storing space comprises a substrate storing die adapted to store at least one substrate.

8. The flat-panel display manufacturing apparatus according to claim 7, wherein the temporary substrate storing space further comprises a gate valve arranged at a region where the temporary substrate storing space and the feeding chamber are connected, to isolate the temporary substrate storing space and the feeding chamber from each other.

9. The flat-panel display manufacturing apparatus according to claim 7, wherein the temporary substrate storing space is separable from the feeding chamber.

10. A vacuum processing apparatus comprising a plurality of vacuum chambers connected to one another to perform a desired process for substrates, wherein at least two of the vacuum chambers are processing chambers vertically stacked and adapted to perform predetermined processes for substrates, respectively.

11. The vacuum processing apparatus according to claim 10, wherein the number of the vertically-stacked processing chambers is two.

12. The vacuum processing apparatus according to claim 11, wherein the processing chambers perform the same function or perform different functions, respectively.

13. The vacuum processing apparatus according to claim 11, wherein the processing chambers are a plasma enhanced etching type dry etching chamber and a reactive ion etching type dry etching chamber, respectively.

14. The vacuum processing apparatus according to claim 11, wherein a lower one of the processing chambers is a reactive ion etching type dry etching chamber, and an upper one of the two processing chambers is a plasma enhanced etching type dry etching chamber.

15. The vacuum processing apparatus according to claim 11, wherein each of the processing chambers is a plasma enhanced etching type dry etching chamber.

16. The vacuum processing apparatus according to claim 11, wherein each of the processing chambers is a reactive ion etching type dry etching chamber.

17. The vacuum processing apparatus according to claim 11, wherein:
an upper one of the processing chambers comprises a top cover vertically movable to open and close the upper processing chamber; and
a lower one of the processing chambers comprises a bottom cover vertically movable to open and close the lower processing chamber.

18. The vacuum processing apparatus according to claim 11, wherein the feeding chamber comprises a feeding robot arranged in the feeding chamber adjacent to the processing chambers such that the feeding robot is vertically movable.

19. A flat-panel display manufacturing apparatus comprising a load lock chamber, a feeding chamber, and a processing chamber, wherein the load lock chamber comprises:
an intermediate wall adapted to divide the interior of the load lock chamber into an upper chamber section and a lower chamber section;
top and bottom covers respectively constituting a top wall of the upper chamber section and a bottom wall of the lower chamber section, the top and bottom covers being vertically movable;
a cover opening/closing unit connected to the top and bottom covers to vertically move the top and bottom covers toward and away from the intermediate wall, and thus, to selectively open and close the upper and lower chamber sections;
gate valves respectively arranged between the upper chamber section and the feeding chamber and the lower chamber section and the feeding chamber to selectively communicate the upper and lower chamber sections with the feeding chamber in accordance with the opening and closing of the upper and lower chamber sections; and
upper and lower loaders respectively mounted to the top and bottom covers, each of the upper and lower loaders being adapted to store at least one object to be processed.

20. The flat-panel display manufacturing apparatus according to claim 19, further comprising:
an exhausting device and a gas supplier installed in each of the upper and lower chamber sections, to enable the upper and lower chamber sections to establish a vacuum state and an atmospheric state independently of each other.

21. The flat-panel display manufacturing apparatus according to claim 19, wherein the cover opening/closing unit comprises:
a movable shaft coupled to the top cover or bottom cover;
a guide member adapted to guide movement of the movable shaft; and
a driver coupled to the movable shaft to vertically move the movable shaft.

22. The flat-panel display manufacturing apparatus according to claim 19, wherein the upper loader comprises a first bottom plate, which is provided at a lower end of the upper loader, and has an area larger than that of the object to be stored in the upper loader.

23. The flat-panel display manufacturing apparatus according to claim 19, wherein the lower loader comprises a second bottom plate, which is provided at a lower end of the lower loader, and has an area larger than that of the object to be stored in the lower loader.

24. The flat-panel display manufacturing apparatus according to claim 19, further comprising:
a controller adapted to control the gate valves to isolate the upper chamber section and the feeding chamber from each other and to communicate the lower chamber section and the feeding chamber with each other when the top cover is vertically moved to open the upper chamber section, and to control the gate valves to isolate the lower chamber section and the feeding chamber from each other and to communicate the upper chamber section and the feeding chamber with each other when the bottom cover is vertically moved to open the lower chamber section.

25. A method for processing substrates, using a flat-panel display manufacturing apparatus including a load lock chamber divided into upper and lower chamber sections, and a feeding chamber connected to the load lock chamber, and a processing chamber connected to the feeding chamber, comprising the steps of:
A) upwardly moving a top cover separably mounted to the upper chamber section in a state of isolating the upper chamber section and the feeding chamber from each other by a gate valve, thereby opening the upper chamber section;
B) loading at least one substrate into an upper substrate loader mounted to a lower surface of the top cover;
C) downwardly moving the top cover, thereby closing the upper chamber section;
D) operating an exhausting device, thereby establishing a vacuum state in the upper chamber section;
E) driving the gate valve, thereby communicating the upper chamber section and the feeding chamber;
F) feeding the substrate loaded in the upper substrate loader into the feeding chamber, and loading the fed substrate into the processing chamber;
G) downwardly moving the bottom cover in a state of isolating the lower chamber section and the feeding chamber from each other by the gate valve, simultaneously with the communication between the upper chamber section and the feeding section at step E), thereby opening the lower chamber section;
H) loading at least one substrate into the upper substrate loader mounted to an upper surface of the bottom cover in the process of feeding the substrate loaded in the upper chamber section into the feeding chamber at step F);
I) upwardly moving the bottom cover, thereby closing the lower chamber section;
J) operating the exhausting device, thereby establishing a vacuum state in the lower chamber section;
K) isolating the upper chamber section and the feeding chamber from each other by the gate valve during execution of step J) for the establishment of the vacuum state in the lower chamber section;
L) driving the gate valve, thereby communicating the lower chamber section and the feeding chamber;
M) feeding the substrate loaded in the lower substrate loader into the feeding chamber, and loading the fed substrate into the processing chamber;
N) loading the substrate completely processed in the processing chamber into the lower substrate loader;
O) upwardly moving the top cover in a state of isolating the upper chamber section and the feeding chamber from each other by the gate valve, simultaneously with the communication between the lower chamber section and the feeding section at step L), thereby opening the upper chamber section; and
P) loading at least one substrate into the lower substrate loader in the process of feeding the substrate loaded in the lower chamber section into the feeding chamber at step F) and loading the processed substrate into the lower substrate loader at step N).

26. The method according to claim 25, wherein each of steps A) to N) is repeatedly executed at least two times.
